(19) United States
(12) Patent Application Publication
(10) Pub. No.: US 2023/0385024 A1
(43) Pub. Date: Nov. 30, 2023

(54) MEMORY CELL BASED ON EDRAM AND CIM COMPRISING THE SAME

(71) Applicant: UIF (University Industry Foundation), Yonsei University, Seoul (KR)

(72) Inventors: Seong-Ook JUNG, Seoul (KR); Do-Han KIM, Seoul (KR); In-Jun JUNG, Seoul (KR)

(21) Appl. No.: 18/312,186

(22) Filed: May 4, 2023

(30) Foreign Application Priority Data
May 26, 2022 (KR) 10-2022-0064532

(51) Int. Cl. G06F 7/44; G11C 11/4096

(52) U.S. Cl. CPC G06F 7/443; G11C 11/4096

(57) ABSTRACT

A memory cell comprises: a weight storage circuit configured, when a write word line is activated, to receive a weight voltage, according to a weight value to be stored through a write bit line, and transmit the weight voltage to a storage node, and, when a read word line is activated, to drop a read voltage precharged, according to a voltage level of the storage node, to a voltage level of the read word line; and a MAC operation circuit configured, when a data enable line is activated, to transmit an input voltage according to a value of input data to a coupling node through a data input line, and, to discharge the coupling node according to a level of the weight voltage stored in the storage node, and, when the data enable line is reactivated, to transmit a voltage change of the coupling node to a multiply word line.

### CROSS-REFERENCE TO RELATED APPLICATIONS

This application claims priority under 35 U.S.C. § 119 from Korean Patent Application No. 10-2022-0064532, filed on May 26, 2022, in the Korean Intellectual Property Office, the disclosure of which is incorporated herein in its entirety by reference.

### BACKGROUND

### 1. Technical Field

Embodiments described herein relate to a memory cell based on eDRAM and a CIM comprising the same, and more particularly to a memory cell based on eDRAM capable of performing a MAC operation and a CIM comprising the same.

### 2. Description of the Related Art

In the case of the existing Von Neumann architecture, since the processor and the memory are separated, and the processor reads data stored in the memory to perform operations, there are limitations in improving energy efficiency and operation speed according to data access and transmission. And recently, due to the development of artificial neural network technology, as MAC (Multiply-Accumulate) operation must be performed on a large scale between input data and weights in DNN (Deep Neural Network) or the like, a technique capable of improving energy efficiency and operation speed is required.

Accordingly, a CIM (Compute-In-Memory, or also referred to as In-Memory Compute) architecture capable of maximizing efficiency by performing operations using a memory for storing data has been proposed. In the CIM architecture, since a memory for storing data directly performs operations without transmitting data to a processor, operations can be performed at low power and high speed by overcoming the limitations of the existing Von Neumann architecture.

In the current CIM architecture, SRAM is mainly used. SRAM is conventionally used as an embedded memory, such as a cache memory, due to its fast operating speed, no need for refresh and compatibility with general logic processes, etc.

SRAM has many advantages as described above, but since each memory cell is generally implemented with 6, 8 or more transistors, a large cell area is required, and, as a result, there is a problem that the memory capacity is limited in a device having a limited size. The limitation of memory capacity requires more frequent access to the external memory to update the weight data when SRAM is applied to the CIM, resulting in lower throughput and energy-efficiency.

Recently, in order to solve the problem caused by the size of the SRAM, a CIM architecture based on embedded DRAM (hereinafter, eDRAM) instead of SRAM has been actively researched. Since eDRAM is implemented based on a DRAM structure, the size of a memory cell can be manufactured to be very small compared to SRAM. Therefore, there is an advantage of having a relatively large memory capacity in the same area. Accordingly, various CIM architectures implemented based on eDRAM have been proposed, and in the existing eDRAM-based CIM architectures, an accumulation operation in a MAC operation is performed based on current. However, an eDRAM-based CIM that performs a MAC operation based on current is vulnerable to PVT variation (Process-Voltage-Temperature variation), and thus has a problem in that operation accuracy is greatly reduced. In addition, depending on the structure of the eDRAM, since the current output as a result of the MAC operation exhibits a nonlinear characteristic, there is a limit in that a compensation circuit or the like to compensate for this is additionally required. In addition, an incorrect operation may be performed because the amount of charge charged in the capacitor of the eDRAM according to the weight is discharged due to leakage current. Accordingly, in consideration of the short retention time of the eDRAM, the refresh cycle (for example, 200 s) should also be set short, and refresh should be performed frequently. If the refresh is performed frequently, the time allotted for performing the operation is reduced, resulting in a decrease in MAC operation speed.

### SUMMARY

An object of the present disclosure is to provide a memory cell based on eDRAM that is robust to PVT variations, has linear characteristics, and can perform a MAC operation without adding a compensation circuit, and a CIM comprising the same.

Another object of the present disclosure is to provide a memory cell based on eDRAM and a CIM comprising the same, which can improve MAC operation efficiency by increasing weight retention time and reducing the number of refreshes.

Another object of the present disclosure is to provide a memory cell based on eDRAM capable of performing a MAC operation on multi-bit input data and a CIM comprising the same.

A memory cell based on eDRAM according to an embodiment of the present disclosure, conceived to achieve the objectives above, comprises a weight storage circuit configured, when a write word line is activated, to receive a weight voltage, according to a weight value to be stored through a write bit line, transmit it to a storage node, and store, and, when a read word line is activated, to drop a read voltage precharged to a read bit line, according to a voltage level of the storage node, to a voltage level of the read word line; and a MAC operation circuit configured, when a data enable line is activated, to transmit an input voltage according to a value of input data to a coupling node through a data input line to charge it, and, to discharge the coupling node according to a level of the weight voltage stored in the storage node so that the coupling node has a voltage corresponding to a product of the input data and the weight, and, when the data enable line is reactivated, to transmit a voltage change of the coupling node to a multiply word line (also referred to as a “MAC word line”) by coupling.

The weight storage circuit may include a write transistor connected between the write bit line and the storage node and having a gate connected to the write word line; and a read transistor connected between the read word line and the read bit line and having a gate connected to the storage node.

The MAC operation circuit may include an operation gate turned on by at least one of activation of the data enable line or a level of the weight voltage to electrically connect the data input line and the coupling node; and a coupling capacitor coupled between the coupling node and the multiply word line.

The operation gate may include a first gate transistor connected between the data input line and the coupling node and having a gate connected to the data enable line; and a second gate transistor connected in parallel with the first gate transistor between the data input line and the coupling node, and having a gate connected to the storage node.

The operation gate may be configured such that, in a data input phase of MAC arithmetic operation, the first gate transistor is turned on according to an activated data enable line to transmit the input voltage applied through the data input line to the coupling node to which the coupling capacitor is connected and charge it, and, after the data input phase, in a multiply phase of the MAC arithmetic operation, while the first gate transistor is turned off by the deactivated data enable line, the second gate transistor is turned off or turned on depending on the level of the weight voltage so that the voltage level of the coupling node can be maintained as an input voltage or can be discharged and decreased through the deactivated data input line.

The operation gate may be configured such that, after the multiply phase, in an accumulate phase of the MAC arithmetic operation, the first gate transistor is turned on according to a reactivated data enable line to electrically connect the coupling node and the deactivated data input line.

When the coupling node and the data input line are electrically connected in the accumulate phase and the voltage level of the coupling node is changed, the coupling capacitor may cause a voltage change in the multiply word line by coupling.

The read transistor is maintained in an on or off state depending on the voltage level of the storage node, and the read transistor in the on state may be configured, when each of the read word line deactivated to a first voltage level and the read bit line precharged with the read voltage in a precharge phase of the read operation is activated to a second voltage level and floated in a subsequent read step of the read operation, to electrically connect the read word line and the read bit line, so that the voltage level of the read bit line drops to the second voltage level.

The write transistor may be configured, when the write word line is activated in a write step of a write operation, to be turned on to apply the input voltage applied through the write bit line to the storage node, and, when the write word line is deactivated at the end of the write step, to be turned off to cause the storage node to float at an applied voltage level.

The write transistor may be implemented with a PMOS transistor, and the read transistor may be implemented with an NMOS transistor.

The memory cell may further include a compensation capacitor connected between the storage node and a compensation control line and coupled to a voltage change of the compensation control line to cause a voltage change of the storage node.

The coupling capacitor may be implemented with a metal-oxide-metal (MOM) capacitor.

A CIM according to an embodiment of the present disclosure, conceived to achieve the objectives above, may comprise a DAC receiving multi-bit input data and converting it into an input voltage; a CIM cell array including a plurality of memory cells configured, during a write operation, to receive and store a weight voltage according to a value of weight, and, during a MAC arithmetic operation, to apply a multiplication operation result of the input voltage with the received and stored weight voltage to multiply word lines, respectively, so that the multiply word lines have a voltage level according to an accumulation result; an ADC detecting voltage levels of the multiply word lines and acquiring MAC operation result values of the input data and the weights; and a sense amplifier circuit for applying the weight voltage to a memory cell, wherein each of the plurality of memory cells may include a write transistor connected between a write bit line to which the weight voltage is applied and a storage node, and having a gate connected to a write word line, a read transistor connected between a read word line and a read bit line and having a gate connected to the storage node, an operation gate turned on by at least one of activation of a data enable line or a voltage level of the storage node to electrically connect a data input line to which the input voltage is applied from the DAC and a coupling node, and a coupling capacitor coupled between the coupling node and the multiply word line.

Accordingly, the memory cell based on eDRAM and the CIM comprising the same according to the embodiment are robust to PVT variations by performing accumulation operation in a charge method, do not require an additional compensation circuit due to its linear characteristics, and can reduce the number of refreshes with a longer retention time than before, so that MAC operation efficiency can be improved by allocating more time to MAC operation, and MAC operation on multi-bit input data can also be performed.

### BRIEF DESCRIPTION OF THE DRAWINGS

FIG. 1 shows a schematic architecture of a CIM according to an embodiment.

FIG. 2 shows a circuit structure of a memory cell in the CIM shown in FIG. 1.

FIG. 3 shows an example of the coupling capacitor structure of FIG. 2.

FIG. 4 shows an example of a design layout for implementing the memory cell of FIG. 2.

FIGS. 5 to 7 are diagrams for explaining a weight write operation of the memory cell of FIG. 2.

FIGS. 8 to 10 are diagrams for explaining a weight read operation of the memory cell of FIG. 2.

FIGS. 11 to 20 are diagrams for explaining a MAC arithmetic operation of the memory cell of FIG. 2.

FIG. 21 shows an example of a detailed architecture of the CIM cell array of FIG. 1.

### DETAILED DESCRIPTION

Hereinafter, specific embodiments of an embodiment will be described with reference to the accompanying drawings. The following detailed description is provided to assist in a comprehensive understanding of the methods, devices and/or systems described herein. However, the detailed description is only for illustrative purposes and the present disclosure is not limited thereto.

In describing the embodiments, when it is determined that detailed descriptions of known technology related to the present disclosure may unnecessarily obscure the gist of the present disclosure, detailed descriptions thereof are omitted here. The terms used below are defined in consideration of functions in the present disclosure, but may be changed depending on the customary practice or the intention of a user or operator. Thus, the definitions should be determined based on the overall content of the present specification. The terms used herein are only for describing the embodiments, and should not be construed as limitative. Unless expressly used otherwise, a singular form includes a plural form. In the present description, the terms “including”, “comprising”, “having”, and the like are used to indicate certain characteristics, numbers, steps, operations, elements, and a portion or combination thereof, but should not be interpreted to preclude one or more other characteristics, numbers, steps, operations, elements, and a portion or combination thereof. Also, terms such as “unit”, “device”, “module”, “block”, and the like described in the specification refer to units for processing at least one function or operation, which may be implemented by hardware, software, or a combination of hardware and software.

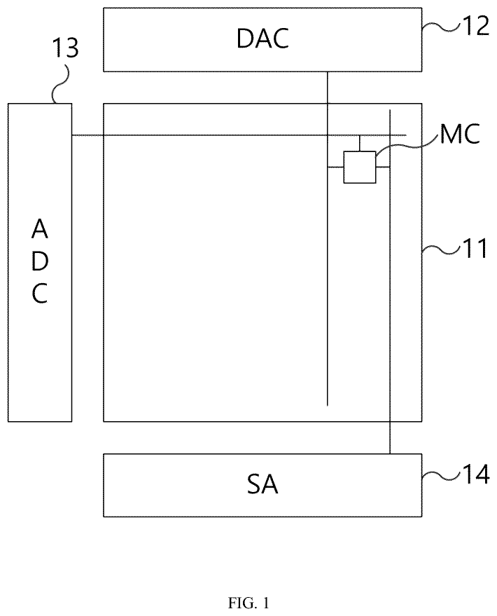

FIG. 1 shows a schematic architecture of a CIM according to an embodiment.

Referring to FIG. 1, the CIM according to the embodiment may include a CIM cell array 11, a digital analog converter (DAC) 12, an analog digital converter (ADC) 13, and a sense amplifier circuit 14. The DAC 12 receives input data (IN), which is digital data, converts it into an analog signal, and applies the converted analog signal to the CIM cell array 11. That is, the DAC 12 applies an analog signal having a voltage level according to the value of the input data (IN) to the CIM cell array 11. At this time, the input data (IN) may be applied as multi-bit data. Accordingly, the DAC 12 may convert the input data (IN) into a multi-level input voltage (VIN) and apply it to the CIM cell array 11.

The CIM cell array 11 includes a plurality of memory cells (MC) that store a weight (W) applied from the sense amplifier circuit 14 and perform MAC operation on the input data (IN) converted into a voltage level and applied from the DAC 12 and the stored weight (W) and output. In an embodiment, the plurality of memory cells (MC) may be implemented with embedded DRAM (eDRAM), and a detailed description of each memory cell (MC) will be described later.

The ADC 13 converts a voltage level resulting from the MAC operation performed on the memory cell (MC) of the CIM cell array 11 into digital data and outputs output data.

The sense amplifier circuit (SA) 14 applies a write voltage according to the value of the weight (W) to the memory cell (MC) during a write operation, and senses and amplifies the value of the weight (W) stored in the memory cell (MC) during a read operation. Even during a refresh operation, the sense amplifier circuit (SA) 14 may sense and amplify the value of the weight (W) stored in the memory cell (MC) and transmit it back to the memory cell (MC), so that the stored weight (W) can be continuously maintained.

Although not shown, the CIM may further include a row decoder (not shown) that selects a plurality of memory cells (MC) arranged in the CIM cell array 11 in a row unit according to a row address among addresses applied together with input data (IN) or weight (W) and a column decoder (not shown) that selects a plurality of memory cells (MC) arranged in the CIM cell array 11 in a column unit according to a column address among applied addresses. In addition, it may further include a control module (not shown) that receives an address, divides it into a row address and a column address, transmits them to a row decoder and a column decoder, and decodes the applied command, thereby controlling CIM components such as row decoder, column decoder, DAC 12, ADC 13 and sense amplifier circuit 14.

When such a CIM is applied to an artificial neural network, the CIM may be used to implement at least one operation layer of the artificial neural network.

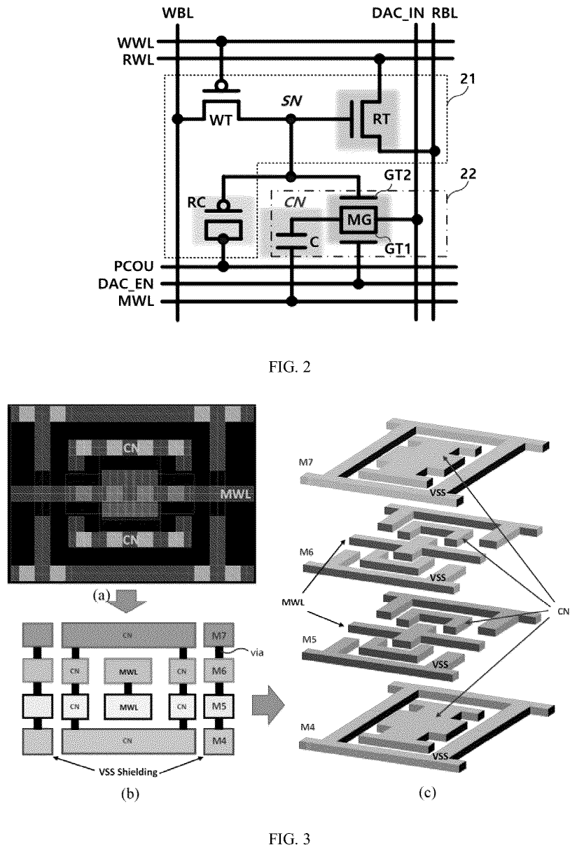

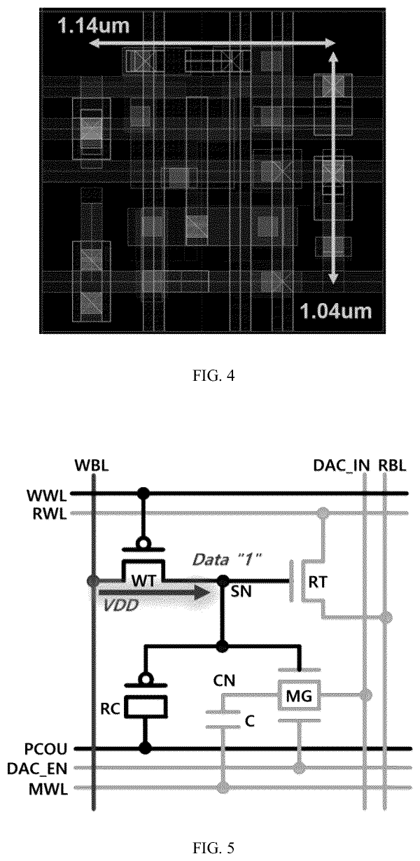

FIG. 2 shows a circuit structure of a memory cell in the CIM shown in FIG. 1, FIG. 3 shows an example of the coupling capacitor structure of FIG. 2, and FIG. 4 shows an example of a design layout for implementing the memory cell of FIG. 2.

Referring to FIG. 2, the memory cell (MC) according to an embodiment includes a weight storage circuit 21 and a MAC operation circuit 22.

The weight storage circuit 21 stores the weight (W). The weight storage circuit 21 is connected between the write word line (WWL) and the write bit line (WBL), the read word line (RWL) and the read bit line (RBL), receives and stores a voltage according to the weight (W) during a write operation of the memory cell (MC), and outputs a voltage according to the stored weight (W) during a read operation.

Specifically, the weight storage circuit 21 includes a read transistor (RT) connected between the read word line (RWL) and the read bit line (RBL) and having a gate connected to the storage node (SN), and a write transistor (WT) connected between the write bit line (WBL) and the storage node (SN), that is, the gate of the read transistor (RT) and having a gate connected to the write word line (WWL).

The write transistor (WT) is turned on when the row decoder (not shown) activates the write word line (WWL) according to a row address during a write operation. And, it transmits a weight voltage (V_{W}) of the first or second voltage level (here, as an example, power supply voltage (V_{DD}) and ground voltage (V_{SS})) applied through the write bit line (WBL) according to the value of the weight (W) from the sense amplifier circuit 14 to the storage node (SN). Here, since the weight voltage (V_{W}) transmitted to the storage node (SN) is connected to the gate of the read transistor (RT), when the write word line (WWL) is deactivated and the write transistor (WT) is turned off, the current path is cut off and the storage node (SN) is maintained at the level of the applied weight voltage (V_{W}). That is, the weight (W) is stored in the storage node (SN).

In addition, since the gate of the read transistor (RT) is connected to the storage node (SN), the read transistor (RT) is turned on or off according to the weight voltage (V_{W}) of the storage node (SN). Accordingly, when the read word line (RWL) is activated by the row decoder during a read operation, the read transistor (RT) transmits or blocks the read voltage (V_{R}) applied from the read bit line (RBL) to the read word line (RWL) according to the level of the weight voltage (V_{W}) of the storage node (SN).

Here, the write transistor (WT) may be implemented with a PMOS transistor, and the read transistor (RT) may be implemented with an NMOS transistor.

Meanwhile, the MAC operation circuit 22 performs MAC operation between the weight (W) stored in the storage node (SN) of the weight storage circuit 21 and the applied input data (IN), and outputs. In particular, in the embodiment, the MAC operation circuit 22 may receive an input voltage (V_{IN}) whose level is divided according to multi-bit (here, 4-bit as an example) input data from the DAC 12, and perform MAC operation on the multi-bit input data and the 1-bit bit value of the stored weight (W), and output.

The MAC operation circuit 22 may include an operation gate (MG) and a coupling capacitor (C) connected in series between the multiply word line (MWL) and the data input line (DAC_IN).

The operation gate (MG) may include two gate transistors (GT1, GT2) connected in parallel between the data input line (DAC_IN) and the coupling node (CN), and the gate of the first gate transistor (GT1) among the two gate transistors (GT1, GT2) is connected to the data enable line (DAC_EN), while the gate of the second gate transistor (GT2) is connected to the storage node (SN). In addition, the coupling capacitor (C) is connected between the multiply word line (MWL) and the coupling node (CN).

Here, since the first and second gate transistors (GT1, GT2) of the operation gate (MG) are connected in parallel between the data input line (DAC_IN) and the coupling node (CN), even when only one of the first and second gate transistors (GT1, GT2) is turned on, the data input line (DAC_IN) and the coupling node (CN) are electrically connected to each other.

Since the gate of the first gate transistor (GT 1) of the operation gate (MG) is connected to the data enable line (DAC_EN), the first gate transistor (GT1) is turned on when the data enable line (DAC_EN) is activated. The first gate transistor (GT1) turned on by the activation of the data enable line (DAC_EN) transmits the input voltage (V_{IN}) from the DAC 12 through the data input line (DAC_IN) to the coupling capacitor (C), so that the coupling capacitor (C) is charged with the applied input voltage (V_{IN}).

In addition, since the gate of the second gate transistor (GT2) is connected to the storage node (SN) having a voltage level according to the weight (W), the second gate transistor (GT2) maintains an on or off state according to the weight voltage (V_{W}). In addition, the second gate transistor (GT2) turned on according to the weight voltage (V_{W}) allows the voltage charged in the coupling capacitor (C) through the data input line (DAC_IN) to be discharged.

The coupling capacitor (C) is first charged by the input voltage (V_{IN}) applied through the operation gate (MG) in the MAC operation step, and then discharges the voltage charged according to the weight voltage (V_{W}) of the storage node (SN) to the data input line (DAC_IN) through the operation gate (MG) again. That is, the coupling capacitor (C) adjusts the voltage level of the coupling node (CN) according to the weight voltage (V_{W}). Further, the coupling capacitor (C) causes the voltage variation of the coupling node (CN) due to the again turned-on second gate transistor (GT2) to also appear on the multiply word line (MWL) through coupling. That is, it causes the multiply word line (MWL) to have a voltage level corresponding to the MAC operation result between the input data and the weight (W).

Existing eDRAM-based CIMs also have a capacitor, because their memory cells are configured based on DRAM. However, in the existing eDRAM-based CIMs, the capacitor provided in the memory cell is used as a storage element for storing the weight (W). On the other hand, in the embodiment, the weight (W) is stored in the form of a voltage level of the storage node (SN), and the coupling capacitor (C) is used as an operation element that temporarily stores input data applied to the coupling node (CN), and then causes an operation result obtained by weighting the input data with a weight (W) to be appeared on the multiply word line (MWL) by coupling.

As the coupling capacitor (C) is used as an analog operation element based on coupling, the coupling capacitor (C) needs to have a size and structure that can be easily coupled between the multiply word line (MWL) and the coupling node (CN) in order to perform accurate arithmetic operations. However, when the size of the coupling capacitor (C) increases, the size of the entire memory cell increases, so in the embodiment, as shown in FIG. 3, the coupling capacitor (C) may be implemented with a metal-oxide-metal (MOM) capacitor implemented as a separate layer from other circuits of the memory cell so that an increase in the size of the memory cell can be suppressed.

Since the MOM capacitor has a laminated structure in which an oxide film layer is interposed between metal layers, it may be implemented by being laminated on a layer different from other circuit configurations. Accordingly, when the coupling capacitor (C) is implemented with a MOM capacitor, an increase in the size of the memory cell due to the coupling capacitor (C) can be minimized. Accordingly, in the embodiment, the coupling capacitor (C) may be implemented with a MOM capacitor using an upper metal layer, which is not generally used when implementing eDRAM. In this case, the layout size of the coupling capacitor (C) implemented in the upper metal layer should be less than or equal to the layout size for implementing the remaining circuits except for the coupling capacitor (C) so that the size of the memory cell is not increased.

FIG. 4 shows a memory cell layout and memory cell size when the coupling capacitor (C) is implemented with a MOM capacitor. In FIG. 4, the memory cell layout is designed based on a 65 nm manufacturing process. In this case, the memory cell may be implemented with a size of 1.14 μm×1.04 μm=1.1856 μm², which is a very small size compared to an SRAM memory cell implemented with a size of 2 μm² or more in the same process, and has a similar or smaller size even compared to other eDRAM-based memory cells.

In FIG. 3, (a) shows an upper layout of the coupling capacitor (C), (b) shows a cross-sectional side view, and (c) shows an exploded perspective view in accordance with layer separation. Referring to FIG. 3, the coupling capacitor (C) may be implemented using metal layers M4 to M7 which are not generally used in eDRAM.

As shown in FIG. 3, the coupling capacitor (C) may be formed to have a structure in which the upper, lower, left and right peripheries of one end of the coupling capacitor (C) connected to the multiply word line (MWL) is completely surrounded by the other end to which the coupling node (CN) is connected, so that coupling between the multiply word line (MWL) and the coupling node (CN) is easily performed. This is because the coupling is more easily performed as the area facing between both ends of the coupling capacitor (C) increases. However, as described above, since it is preferable that the size of the layout of the coupling capacitor (C) is implemented less than or equal to the size of the layout for implementing the remaining circuits, even if it has a structure in which the other end to which the coupling node (CN) is connected surrounds one end, a required level of coupling may not be achieved. Accordingly, here, the size of one end is increased by implementing one end of the coupling capacitor (C) in two metal layers of M5 and M6 and electrically connecting them to each other through a via. In addition, one end of the coupling capacitor (C) is formed with a stub protruding in both directions in the direction of travel to the multiply word line (MWL), so that a coupling area with the coupling node (CN) at the other end can be increased.

The other end of the coupling capacitor (C) surrounds sides of the one end in the two metal layers of M5 and M6, and is also formed on the upper and lower sides of one end in the M4 and M7 metal layers, so that the other end of the coupling capacitor (C) can completely surround peripheries of the one end. At this time, the other ends separately formed in the M4 to M7 metal layers are also electrically connected to each other through vias.

Additionally, a ground line may be formed outside the other end of the coupling capacitor (C) in the M4 to M7 metal layers to isolate the coupling capacitor (C) from external influences.

Meanwhile, as described above, the memory cell of the embodiment stores the weight voltage (V_{W}) according to the weight (W) having a bit value of 1 bit in the storage node (SN). Accordingly, when the weight (W) has a bit value of “1” during a write operation, a first voltage (here, for example, power supply voltage (V_{DD})) corresponding to the bit value of “1” may be applied to the write bit line (WBL), and when the weight (W) has a bit value of “0”, a second voltage (here, as an example, ground voltage (V_{SS})) may be applied to the write bit line (WBL).

Accordingly, as shown in FIG. 2, if the write transistor (WT) connecting the write bit line (WBL) and the storage node (SN) is implemented with a PMOS transistor, when the weight (W) to be stored has a bit value of “1”, the write transistor (WT) may pull up the storage node (SN) to the first voltage level. However, when the weight (W) to be stored has a bit value of “0”, the storage node (SN) is not pulled down to the second voltage level by the threshold voltage (V_{TH}) of the write transistor (WT). And the gate of the second gate transistor (GT2) of the operation gate (MG) is connected to the storage node (SN), and accordingly, the second gate transistor (GT2) is turned on or off depending on the voltage level of the storage node (SN). Therefore, if the storage node (SN) is not pulled down to the second voltage level, the second gate transistor (GT2) may not be stably driven, and thus there is a possibility that an error may occur in the MAC operation.

Accordingly, the weight storage circuit 21 of the embodiment may further include a compensation capacitor (RC) for preventing an operation error caused by the threshold voltage (V_{TH}) of the write transistor (WT) from occurring. The compensation capacitor (RC) is connected between the storage node (SN) and the compensation control line (PCOU). The compensation control line (PCOU) is first activated before the write word line (WWL) is activated during a write operation, and deactivated before the write word line (WWL) is deactivated. Further, the compensation capacitor (RC) reflects the voltage variation of the compensation control line (PCOU) to the storage node (SN) by coupling, so that the storage node (SN) can have the second voltage level when the weight (W) has a bit value of “0”. Here, the compensation capacitor (RC) may be implemented with, for example, a MOS capacitor, and in particular, as shown in FIG. 2, it may be implemented with a PMOS capacitor.

In addition, since the compensation capacitor (RC) is just a component for compensating the voltage level of the storage node (SN) by the threshold voltage (V_{TH}) of the write transistor (WT) implemented with a PMOS transistor, it does not matter if it is not implemented with a large-sized capacitor. Accordingly, the compensation capacitor (RC) may be implemented with a MOS capacitor, unlike the coupling capacitor (C) implemented with a MOM capacitor.

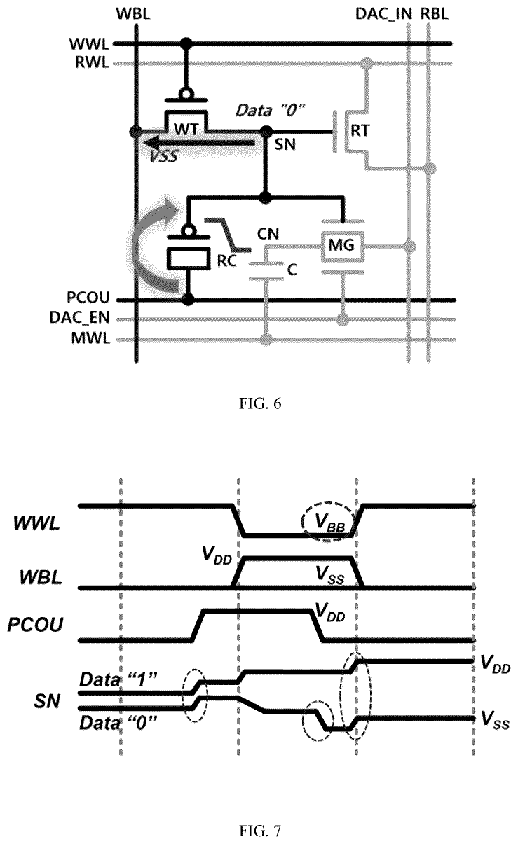

FIGS. 5 to 7 are diagrams for explaining a weight write operation of the memory cell of FIG. 2. FIG. 5 is a diagram for explaining an operation in which a weight “1” is written to a memory cell (MC), FIG. 6 is a diagram for explaining an operation in which a weight “0” is written, and FIG. 7 shows a timing diagram for the write operation of FIGS. 5 and 6.

Referring to FIGS. 5 to 7, the write operation of the memory cell (MC) may be performed by being divided into a preliminary step and a write step.

Before the write operation, the write word line (WWL) is deactivated to a first voltage level, and the write bit line (WBL) and compensation control line (PCOU) remain deactivated to a second voltage level. At this time, the storage node (SN) may maintain the previously applied weight voltage (V_{W}). Here, for convenience of description, it is assumed that the storage node (SN) arbitrarily has a weight voltage (V_{W}) between the first voltage level and the second voltage level.

In addition, the preliminary step is performed before the write step of storing the weight voltage (V_{W}) according to the weight (W) of the memory cell (MC). That is, in the preliminary step before the write word line (WWL) is activated by the row decoder in the write step, the compensation control line (PCOU) may first be activated to a first voltage level. In this case, the compensation control line (PCOU) may be activated according to the control of a control module (not shown). Similar to the write word line (WWL), the compensation control line (PCOU) may be activated when a row decoder driven by the control module applies the first voltage to the compensation control line (PCOU) corresponding to a row address.

When the compensation control line (PCOU) is activated to the first voltage level, the compensation capacitor (RC) connected between the storage node (SN) and the compensation control line (PCOU) increases the voltage level of the storage node (SN) by coupling a voltage change of the compensation control line (PCOU).

Thereafter, in the write step, the write word line (WWL) is activated to a second voltage level or a third voltage level (here, as an example, bias voltage (V_{BB})), and thus the write transistor (WT) is turned on, and to the write bit line (WBL), the write voltage (V_{W}) according to the value of the weight (W) is applied at a first voltage level or a second voltage level. Since the write transistor (WT) is turned on, the write voltage (V_{W}) applied through the write bit line (WBL) is transmitted to the storage node (SN). At this time, as described above, even if the write voltage (V_{W}) of the second voltage level is applied to the write bit line (WBL), the voltage level of the storage node (SN) does not drop to the second voltage level due to the threshold voltage (V_{TH}) of the write transistor (WT).

However, if the compensation control line (PCOU) is deactivated to the second voltage level after the write word line (WWL) is activated, the compensation capacitor (RC) couples the voltage change of the compensation control line (PCOU) to lower the voltage level of the storage node (SN) to a voltage level lower than the second voltage. After the compensation control line (PCOU) is deactivated, the write word line (WWL) and the write bit line (WBL) are deactivated to a first voltage level and a second voltage level, respectively. At this time, when the write word line (WWL) is deactivated to the first voltage level and thus the write transistor (WT) is turned off, the voltage level of the storage node (SN) instantaneously rises to a certain level by the turned off write transistor (WT), and as a result, the storage node (SN) has a first voltage level or a second voltage level. That is, it has a weight voltage (V_{W}) according to the value of the weight (W).

As a result, in the embodiment, by activating and deactivating the compensation control line (PCOU) before the write word line (WWL), in spite of the threshold voltage (V_{TH}) of the write transistor (WT), the storage node (SN) can have a weight voltage (V_{W}) according to the value of the weight (W).

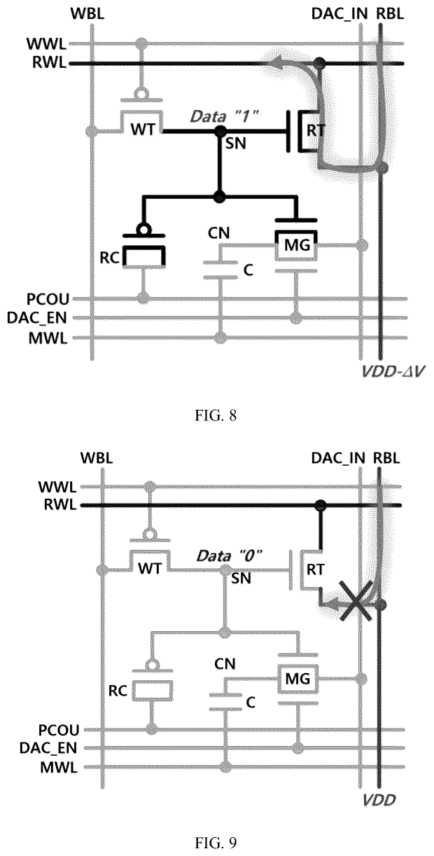

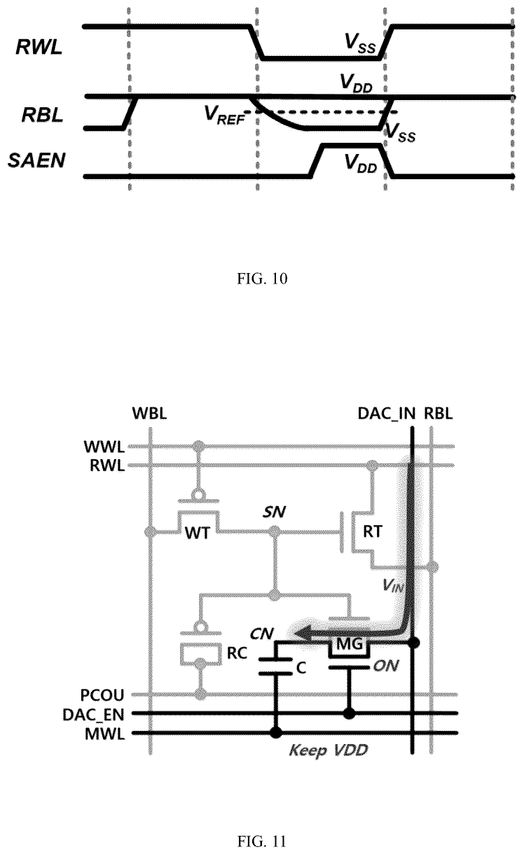

FIGS. 8 to 10 are diagrams for explaining a weight read operation of the memory cell of FIG. 2. FIG. 8 is a diagram for explaining an operation in which a weight “1” is read to a memory cell (MC), FIG. 9 is a diagram for explaining an operation in which a weight “0” is read, and FIG. 10 shows a timing diagram for read operations of FIGS. 8 and 9.

Referring to FIGS. 8 to 10, the read operation of the memory cell (MC) may be divided into a pre-charge step and a read step.

Prior to a read operation of the memory cell (MC), the read transistor (RT) is turned on or off depending on the weight (W) stored in the storage node (SN). If the value of the stored weight (W) is “1”, the weight voltage (V_{W}) of the storage node (SN) has a first voltage level, and thus the read transistor (RT) is maintained in a turned-on state. On the other hand, when the value of the stored weight (W) is “0”, the weight voltage (V_{W}) of the storage node (SN) has a second voltage level, and thus the read transistor (RT) is maintained in a turned-off state.

In addition, in the pre-charge step, the read word line (RWL) is deactivated to a first voltage level, and the read bit line (RBL) is precharged to a read voltage (V_{R}) level (herein, first voltage as an example). At this time, since the same first voltage level is applied to both the read word line (RWL) and the read bit line (RBL), regardless of whether the read transistor (RT) is turned on or off, the read word line (RWL) and the read bit line (RBL) have a first voltage level.

After that, in the read step, the read word line (RWL) is activated to the second voltage level by the row decoder, and no voltage is applied to the read bit line (RBL), so that it floats at the level of the precharged read voltage (V_{R}). When the read word line (RWL) is activated to the second voltage level, the voltage level of the read bit line (RBL) precharged to the read voltage (V_{R}) level appears differently depending on the turned-on or turned-off state of the read transistor (RT).

If the value of the weight (W) stored in the storage node (SN) is “0”, since the read transistor (RT) is in the turned-off state, the read word line (RWL) and the read bit line (RBL) are in a electrically cut-off state. Accordingly, the voltage level of the read bit line (RBL) is maintained at the level of the precharged read voltage (V_{R}). On the other hand, when the value of the weight (W) stored in the storage node (SN) is “1”, since the read transistor (RT) is in the turned-on state, the read word line (RWL) and the read bit line (RBL) are in a electrically connected state. Accordingly, the voltage level of the read bit line (RBL) is lowered to the second voltage level, which is the voltage level of the read word line (RWL). That is, the voltage of the read bit line (RBL) appears differently depending on the value of the weight (W) stored in the storage node (SN). Accordingly, the sense amplifier circuit (not shown) may compare the voltage of the read bit line (RBL) with a reference voltage (V_{REF}), amplify it to determine the value of the weight value (W) stored in the memory cell (MC).

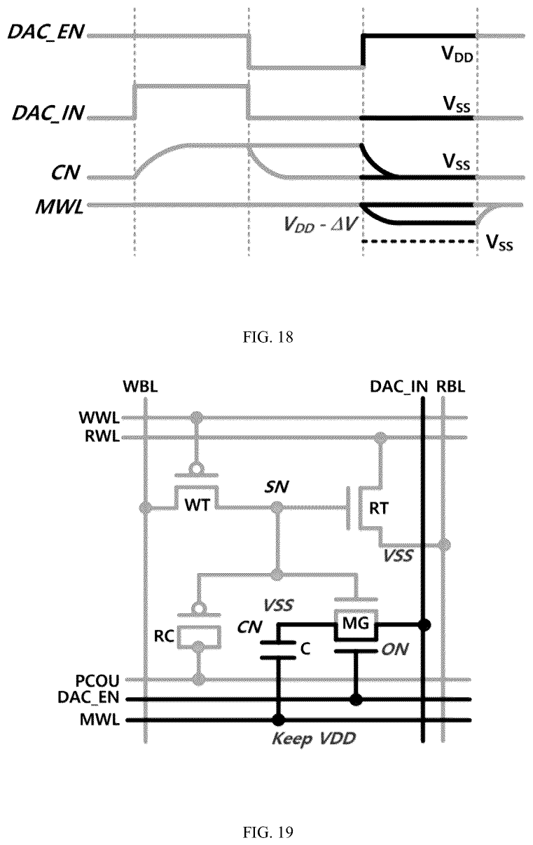

FIGS. 11 to 20 are diagrams for explaining a MAC arithmetic operation of the memory cell of FIG. 2.

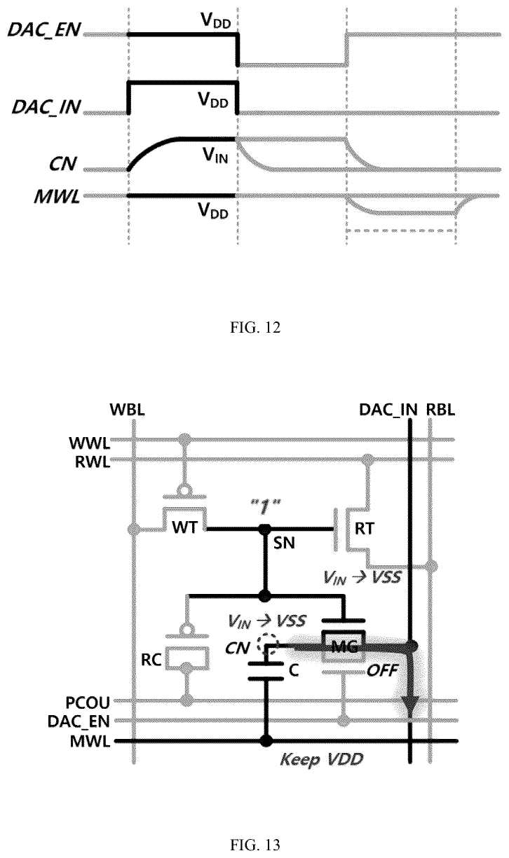

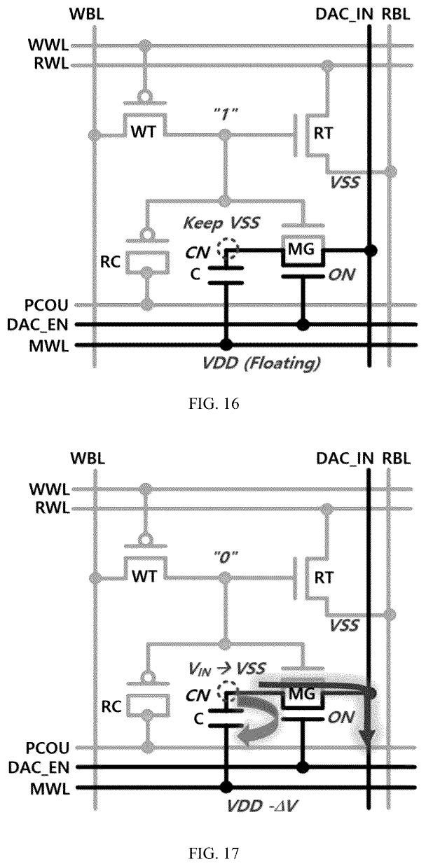

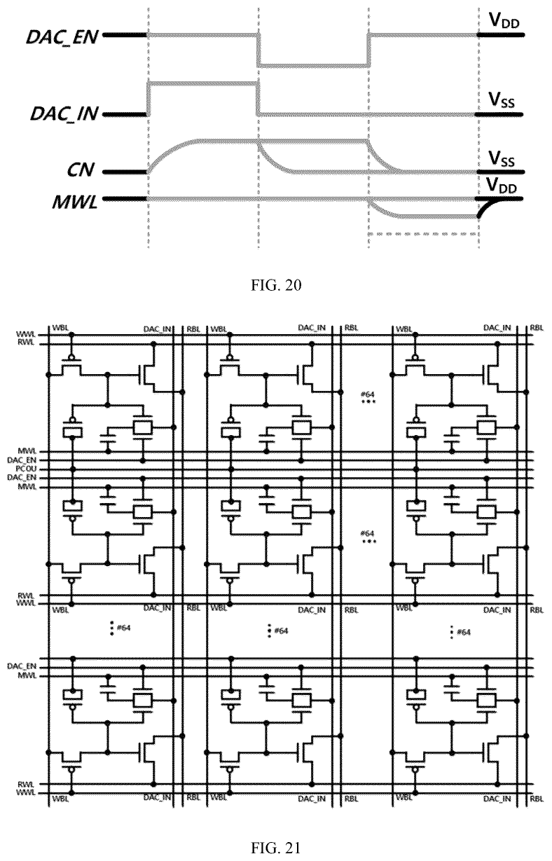

The MAC arithmetic operation of the memory cell of the embodiment can be largely divided into a data input phase, a multiply phase, an accumulate phase and a precharge phase. FIGS. 11 and 12 are diagrams for explaining an input phase, FIGS. 13 to 15 are diagrams for explaining a multiply phase, and FIGS. 16 to 18 are diagrams for explaining an accumulate phase. In addition, FIGS. 19 and 20 are diagrams for explaining a precharge phase.

Referring to FIGS. 11 and 12, in the input phase, the DAC 12 is activated so that the data enable line (DAC_EN) is activated to a first voltage level, and the multiply word line (MWL) remains precharged to the first voltage level in the previous precharge phase. Accordingly, the first gate transistor (GT1) of the operation gate (MG) is turned on by the activated data enable line (DAC_EN) to electrically connect the coupling node (CN) and the data input line (DAC_IN). At this time, the second gate transistor (GT2) of the operation gate (MG) can be maintained in an on or off state depending on the weight (W) stored in the storage node (SN), but since the first gate transistor (GT1) is turned on, the coupling node (CN) and the data input line (DAC_IN) are electrically connected regardless of whether the second gate transistor (GT2) is turned on or off.

In addition, the input voltage (V_{IN}) according to the input data (IN) from the DAC 12 is applied to the coupling capacitor (C) through the data input line (DAC_IN) and the operation gate (MG). As described above, in the present embodiment, the input data (IN) may be multi-bit data, and thus the input voltage (V_{IN}) may have various voltage levels between the first voltage and the second voltage.

The coupling capacitor (C) is charged by receiving the input voltage (V_{IN}) so that the voltage level of the coupling node (CN) becomes the input voltage (V_{IN}). At this time, the multiply word line (MWL) maintains a precharged state at the first voltage level.

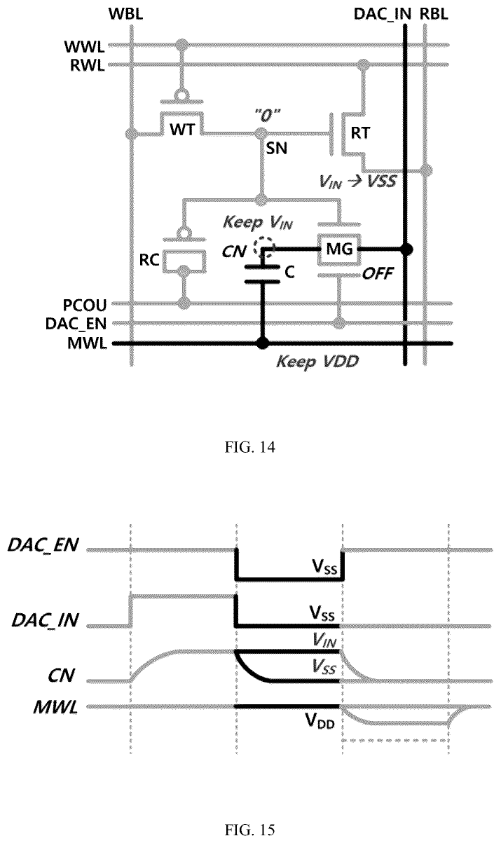

FIG. 13 shows a multiply phase in a state where the weight (W) “1” is stored in the storage node (SN), and FIG. 14 shows a multiply phase in a state where the weight (W) “0” is stored.

The second gate transistor (GT2) maintains an on state in a state where the weight (W) “1” is stored in the storage node (SN), and maintains an off state in a state where “0” is stored. In addition, in the multiply phase, the data enable line (DAC_EN) is deactivated to the second voltage level, and the data input line (DAC_IN) is also deactivated to the second voltage level regardless of the input data (IN). However, the multiply word line (MWL) remains precharged to the first voltage level.

First, referring to FIG. 13, since the first gate transistor (GT1) is turned off by the deactivated data enable line (DAC_EN), but the second gate transistor (GT2) remains on, the coupling node (CN) and the data input line (DAC_IN) are electrically connected. In addition, since the data input line (DAC_IN) is deactivated to the second voltage level, the voltage level of the coupling node (CN) charged by the input voltage (V_{IN}) is discharged to the second voltage level.

On the other hand, in FIG. 14, since the second gate transistor (GT2) remains off and the first gate transistor (GT1) is turned off, the coupling node (CN) and the data input line (DAC_IN) are electrically cut off. Accordingly, the voltage level of the coupling node (CN) maintains the charged input voltage (V_{IN}).

That is, it can be regarded that, in the multiply phase, since the voltage level of the coupling node (CN) is maintained at the input voltage (V_{IN}) or erased to the second voltage depending on the value of the weight (W), the result of multiplying the input data (IN) and the weight (W) appears in the coupling node (CN).

FIG. 16 shows an accumulate phase in a state in which a weight (W) “1” is stored in a storage node (SN), and FIG. 17 shows an accumulate phase in a state in which a weight (W) “0” is stored.

In the accumulate phase, the data enable line (DAC_EN) is activated again to the first voltage level, and thus the first gate transistor (GT1) is turned on. In addition, the data input line (DAC_IN) maintains a state deactivated to the second voltage level, and the multiply word line (MWL) floats in a precharged state with the first voltage level.

Referring to FIG. 16, even if the first gate transistor (GT1) is turned on and thus the coupling node (CN) and the data input line (DAC_IN) are electrically connected, since the voltage level of the coupling node (CN) has already dropped to the second voltage level in the multiply phase, no voltage change occurs at the coupling node (CN). Accordingly, since the coupling phenomenon does not occur even in the coupling capacitor (C), the multiply word line (MWL) maintains the precharged first voltage level.

On the other hand, in FIG. 17, when the first gate transistor (GT1) is turned on and thus the coupling node (CN) and the data input line (DAC_IN) are electrically connected, the voltage level of the coupling node (CN) having the input voltage (V_{IN}) level drops to the second voltage level. The voltage drop of the coupling node (CN) appears as a voltage level drop of the multiply word line (MWL) coupled by the coupling capacitor (C). That is, the voltage level of the multiply word line (MWL) precharged to the first voltage level is reduced by the voltage (ΔV) due to the coupling.

From the point of view of a single memory cell (MC), this can be regarded that the multiplication result of the input data (IN) and the weight (W) is simply reflected on the multiply word line (MWL), however since a plurality of memory cells (MC) are arranged in the CIM cell array 11, when each of the at least one memory cell (MC) connected to the same multiply word line (MWL) reduces the voltage of the multiply word line (MWL) as a result of multiplication, the voltage level of the multiply word line (MWL) appears by accumulating multiplication results of each memory cell. That is, it appears in the same form as performing the cumulative operation. In addition, the ADC 13 may obtain a MAC operation result by converting the voltage level of the multiply word line (MWL) into a digital value.

When the MAC operation result is obtained, for the next MAC operation, the multiply word line (MWL) should be precharged. Accordingly, as shown in FIGS. 19 and 20, the multiply word line (MWL) is precharged again to the first voltage level. Even in the precharge phase, the data enable line (DAC_EN) remains activated to the first voltage level, and the data input line (DAC_IN) remains deactivated to the second voltage level.

FIG. 21 shows an example of a detailed architecture of the CIM cell array 11 of FIG. 1.

FIG. 21 illustrates a CIM cell array in which memory cells (MC) are arranged in a size of 64*64 as an example. As shown in FIG. 21, in the CIM cell array, a plurality of write word lines (WWL), a plurality of read word lines (RWL), multiply word lines (MWL), data enable lines (DAC_EN) and compensation control lines (PCOU) may be arranged to extend in a first direction, and a plurality of write bit lines (WBL), read bit lines (RBL) and data input lines (DAC_IN) may be arranged to extend in a second direction perpendicular to the first direction. Here, the first direction may be a row direction, and the second direction may be a column direction.

In addition, among the plurality of lines extending in the first direction, the compensation control line (PCOU) may be commonly used by memory cells (MC) arranged in two adjacent rows. That is, as shown in FIG. 21, the compensation control line (PCOU) may be used in common by disposing one line in two rows. This is because the compensation control line (PCOU) is not directly related to the weight (W), input data (IN), or MAC operation, but is simply a line used to compensate the voltage level of the storage node (SN).

As a result, the memory cell (MC) of the CIM according to the present embodiment is implemented based on eDRAM and thus can be manufactured in a small size, read and write the weight (W), and perform a MAC operation with multi-bit input data (IN). In this case, since the cumulative operation is performed in a voltage charge method rather than a current, an accurate MAC operation can be robustly performed even in the case of a PVT variation. Moreover, since a signal path for performing a read or write operation and a signal path for performing a MAC operation are separated from each other in each memory cell (MC), a very stable operation can be performed. In addition, since the weight (W) is not stored in the capacitor (C) and maintained at the voltage level of the storage node (SN), the retention time is increased. Accordingly, since the refresh cycle can be increased and thus more time can be allocated to the MAC operation, operation performance can be improved.

Although the present disclosure has been described in detail through representative examples above, a person having ordinary skill in the art would understand that many variations and other equivalent embodiments can be derived from the embodiments described herein. Therefore, the true technical scope of the present disclosure is to be defined by the technical spirit set forth in the appended scope of claims.

What is claimed is:

1. A memory cell for compute-in-memory (CIM) comprising:
a weight storage circuit configured,
when a write word line is activated, to receive a weight voltage, according to a weight value to be stored through a write bit line, to transmit the weight voltage to a storage node, and to store the weight voltage in the storage node, and,
when a read word line is activated, to drop a read voltage precharged to a read bit line, according to a voltage level of the storage node, to a voltage level of the read word line; and
a multiply-accumulate (MAC) operation circuit configured,
when a data enable line is activated, to transmit an input voltage according to a value of input data to a coupling node through a data input line to charge the coupling node, and, to discharge the coupling node according to a level of the weight voltage stored in the storage node so that the coupling node has a voltage corresponding to a product of the input data and the weight, and,
when the data enable line is reactivated, to transmit a voltage change of the coupling node to a multiply word line by coupling.

2. The memory cell for CIM according to claim 1,
wherein the weight storage circuit includes:
a write transistor connected between the write bit line and the storage node and having a gate connected to the write word line; and
a read transistor connected between the read word line and the read bit line and having a gate connected to the storage node.

3. The memory cell for CIM according to claim 2,
wherein the MAC operation circuit includes:
an operation gate turned on by at least one of activation of the data enable line or a level of the weight voltage to electrically connect the data input line and the coupling node; and
a coupling capacitor coupled between the coupling node and the multiply word line.

4. The memory cell for CIM according to claim 3,
wherein the operation gate includes:
a first gate transistor connected between the data input line and the coupling node and having a gate connected to the data enable line; and
a second gate transistor connected in parallel with the first gate transistor between the data input line and the coupling node, and having a gate connected to the storage node.

5. The memory cell for CIM according to claim 4,
wherein the operation gate is configured such that,
in a data input phase of MAC arithmetic operation, the first gate transistor is turned on according to an activated data enable line to transmit the input voltage applied through the data input line to the coupling node to which the coupling capacitor is connected and charge the coupling node, and,
after the data input phase, in a multiply phase of the MAC arithmetic operation, while the first gate transistor is turned off by the deactivated data enable line, the second gate transistor is turned off or turned on depending on the level of the weight voltage so that the voltage level of the coupling node is maintained as an input voltage or is discharged and decreased through the deactivated data input line.

6. The memory cell for CIM according to claim 5,
wherein the operation gate is configured such that, after the multiply phase, in an accumulate phase of the MAC arithmetic operation, the first gate transistor is turned on according to a reactivated data enable line to electrically connect the coupling node and the deactivated data input line.

7. The memory cell for CIM according to claim 6,
wherein, when the coupling node and the data input line are electrically connected in the accumulate phase and the voltage level of the coupling node is changed, the coupling capacitor causes a voltage change in the multiply word line by coupling.

8. The memory cell for CIM according to claim 7,
wherein the multiply word line has a voltage level at which voltage changes caused by a plurality of connected memory cells are accumulated.

9. The memory cell for CIM according to claim 3,
wherein the read transistor is maintained in an on or off state depending on the voltage level of the storage node, and
the read transistor in the on state is configured, when each of the read word line deactivated to a first voltage level and the read bit line precharged with the read voltage in a precharge phase of the read operation is activated to a second voltage level and floated in a subsequent read step of the read operation, to electrically connect the read word line and the read bit line, so that the voltage level of the read bit line drops to the second voltage level.

10. The memory cell for CIM according to claim 9,
wherein the write transistor is configured,
when the write word line is activated in a write step of a write operation, to be turned on to apply the input voltage applied through the write bit line to the storage node, and,
when the write word line is deactivated at the end of the write step, to be turned off to cause the storage node to float at an applied voltage level.

11. The memory cell for CIM according to claim 10,
wherein the write transistor is implemented with a PMOS transistor, and
the read transistor is implemented with an NMOS transistor.

12. The memory cell for CIM according to claim 11,
wherein the memory cell further includes
a compensation capacitor connected between the storage node and a compensation control line and coupled to a voltage change of the compensation control line to cause a voltage change of the storage node.

13. The memory cell for CIM according to claim 12,
wherein the compensation control line
is activated before the write word line is activated, thereby increasing the voltage level of the storage node, and
is deactivated before the write word line is deactivated, thereby lowering the voltage level of the storage node.

14. The memory cell for CIM according to claim 13,
wherein the compensation capacitor is implemented with a Metal-Oxide-Metal (MOS) capacitor.

15. The memory cell for CIM according to claim 3,
wherein the coupling capacitor is implemented with a Metal-Oxide-Metal (MOM) capacitor.

16. The memory cell for CIM according to claim 15,
wherein one end of the coupling capacitor connected to the multiply word line is formed on at least one metal layer, and
the other end of the coupling capacitor connected to the coupling node is formed on a metal layer disposed to surround the lateral periphery of the metal layer on which the one end is formed and upper and lower portions of the metal layer on which the one end is formed.

17. The memory cell for CIM according to claim 16,
wherein, when one ends of the coupling capacitor are formed in a plurality of metal layers, the one ends formed in a plurality of metal layers are electrically connected to each other through a via, and
the other ends formed in a plurality of metal layers are also electrically connected to each other through a via.

18. The memory cell for CIM according to claim 1,
wherein the weight has a 1-bit data value, and the input data has a multi-bit data value.

19. A compute-in-memory (CIM) comprising:
a digital analog converter (DAC) receiving multi-bit input data and converting the multi-bit input data into an input voltage;
a CIM cell array including a plurality of memory cells configured, during a write operation, to receive and store a weight voltage according to a value of weight, and, during a multiply-accumulate (MAC) arithmetic operation, to apply a multiplication operation result of the input voltage with the received and stored weight voltage to multiply word lines, respectively, so that the multiply word lines have a voltage level according to an accumulation result;
an analog digital converter (ADC) detecting voltage levels of the multiply word lines and acquiring MAC operation result values of the input data and the weights; and
a sense amplifier circuit for applying the weight voltage to a memory cell,
wherein each of the plurality of memory cells includes
a write transistor connected between a write bit line to which the weight voltage is applied and a storage node, and having a gate connected to a write word line, a read transistor connected between a read word line and a read bit line and having a gate connected to the storage node,
an operation gate turned on by at least one of activation of a data enable line or a voltage level of the storage node to electrically connect a data input line to which the input voltage is applied from the DAC and a coupling node, and
a coupling capacitor coupled between the coupling node and the multiply word line.
